(19) United States
(12) Patent Application Publication
(10) Pub. No.: US 2025/0318435 A1
(43) Pub. Date: Oct. 9, 2025

(54) MANUFACTURING METHOD FOR MAGNETO RESISTIVE SENSOR

(71) Applicant: TDK Corporation, Tokyo (JP)

(72) Inventors: Toshihide SUTO, Tokyo (JP); Kazuya WATANABE, Tokyo (JP); Hiraku HIRABAYASHI, Tokyo (JP)

(73) Assignee: TDK Corporation, Tokyo (JP)

(21) Appl. No.: 18/625,412

(22) Filed: Apr. 3, 2024

(51) Int. Cl. H10N 50/01; G01D 5/16; H10N 50/10

(52) U.S. Cl. CPC H10N 50/01; G01D 5/16; H10N 50/10

(57) ABSTRACT

A manufacturing method for a magneto resistive sensor includes a first magnetization step for magnetizing a first area of an antiferromagnetic layer by applying a magnetic field in a first magnetization direction and irradiating the first area with a laser beam, and a second magnetization step for magnetizing a second area of the antiferromagnetic layer, the second area not overlapping the first area, after the first magnetization step by applying a magnetic field in a second magnetization direction that differs from the first magnetization direction and irradiating the second area with the laser beam.

### FIELD

The present disclosure relates to a manufacturing method for a magneto resistive sensor.

### BACKGROUND

In recent years, many devices and sensors using magnetoresistance have been proposed. For example, a magnetic sensor that detects a rotation angle of an object or the like using a GMR (Giant Magneto Resistance) element or a TMR (Tunneling Magneto Resistance) element has been proposed, and since GMR and TMR exhibit superior magnetoresistance, the characteristics thereof are widely used to enable construction of superior magnetic sensors.

A magnetoresistance element using GMR or TMR is provided with a free layer and a magnetization fixed layer. The magnetization fixed layer can be formed by, for example, annealing a laminated body including an antiferromagnetic layer and a ferromagnetic layer formed on a substrate while applying a magnetic field, and determining a magnetization direction by magnetizing the ferromagnetic layer.

### SUMMARY

A manufacturing method for a magneto resistive sensor according to an aspect of the present disclosure is a method for manufacturing a magneto resistive sensor including a plurality of magnetoresistance elements, each of which includes a magnetization fixed layer having a laminated structure of an antiferromagnetic film and a ferromagnetic film, the manufacturing method including a first magnetization step for magnetizing a first area of the antiferromagnetic layer by applying a magnetic field in a first magnetization direction and irradiating the first area with a laser beam, and a second magnetization step for magnetizing a second area of the antiferromagnetic layer, the second area not overlapping the first area, after the first magnetization step by applying a magnetic field in a second magnetization direction that differs from the first magnetization direction and irradiating the second area with the laser beam, wherein the second area is adjacent to the first area with a buffer area therebetween, and in the second magnetization step, irradiation with the laser beam is performed so that a maximum temperature of the first area remains below a blocking temperature.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a view showing a configuration of a magneto resistive sensor according to one example embodiment;

FIG. 2 is a view showing a circuit configuration of a first magneto resistive sensor unit according to the example embodiment;

FIG. 3 is a view showing a circuit configuration of a second magneto resistive sensor unit according to the example embodiment;

FIG. 4 is a perspective view showing a schematic configuration of a magnetoresistance element according to the example embodiment;

FIG. 5 is a view showing four resistance units of the first magneto resistive sensor unit according to the example embodiment;

FIG. 6 is a view showing four resistance units of the second magneto resistive sensor unit according to the example embodiment;

FIG. 7 is a view showing a configuration of the resistance unit according to the example embodiment;

FIG. 8 is a block diagram showing a schematic configuration of a sensor unit 100A according to the example embodiment;

FIG. 9A is a view showing a manufacturing method for the magneto resistive sensor according to the example embodiment;

FIG. 9B is a view showing the manufacturing method for the magneto resistive sensor according to the example embodiment;

FIG. 9C is a view showing the manufacturing method for the magneto resistive sensor according to the example embodiment;

FIG. 9D is a view showing the manufacturing method for the magneto resistive sensor according to the example embodiment;

FIG. 10A is a view showing the manufacturing method for the magneto resistive sensor according to the example embodiment;

FIG. 10B is a view showing the manufacturing method for the magneto resistive sensor according to the example embodiment;

FIG. 11A is a view showing a magnetization process for the magneto resistive sensor according to the example embodiment;

FIG. 11B is a view showing the magnetization process for the magneto resistive sensor according to the example embodiment;

FIG. 12 is a view showing the magnetization process for the magneto resistive sensor according to the example embodiment; and

FIG. 13 is a view showing a laser annealing device according to the example embodiment.

### DETAILED DESCRIPTION

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

One example embodiment (also referred to hereinafter as “the example embodiment”) of the present disclosure will be described below with reference to the attached drawings. Note that in the drawings attached to the specification, scale and aspect ratios and so on may be modified or exaggerated from the actual ratios and so on as appropriate for convenience in terms of illustration and ease of understanding.

Some of the drawings described below illustrate an X axis, a Y axis, and a Z axis. The X axis, Y axis, and Z axis form right-handed, three-dimensional Cartesian coordinates. Hereinafter, the direction of an arrow on the X axis may be referred to as a +X direction, and the opposite direction to the arrow may be referred to as a −X direction. This applies likewise to the other axes. Note that the +Z direction and the −Z direction may also be referred to respectively as “the upper side” or “upward” and “the lower side” or “downward”. Further, the Z axis direction may also be referred to as a “lamination direction”. Furthermore, planes respectively orthogonal to the X axis, the Y axis, and the Z axis may be referred to as a YZ plane, a ZX plane, and an XY plane. Note, however, that these directions and so on are used for convenience to illustrate relative positional relationships. Accordingly, these directions and so on do not define absolute positional relationships.

Furthermore, in the following, terms and/or numerical values signifying shapes and/or geometrical conditions do not need to be tied to strict meanings and may be interpreted to include ranges in which similar functions can be expected. For example, “parallel” and/or “orthogonal” and so on correspond to the terms described above. Moreover, “the value of the length” and/or “the value of the angle”, and so on correspond to the numerical values described above.

In addition, expressions indicating that a certain configuration is “above”, “below”, “on the upper side of”, “on the lower side of”, “upward of”, or “downward of” another configuration may include aspects in which the certain configuration is in direct contact with the other configuration and aspects in which a separate configuration is included between the certain configuration and the other configuration. An aspect in which a separate configuration is included between the certain configuration and the other configuration may be expressed as an aspect in which the certain configuration is in indirect contact with the other configuration. Furthermore, the expressions “above”, “the upper side”, and “upward” are interchangeable with the expressions “below”, “the lower side”, and “downward”. In other words, the up-down direction may be reversed. This applies similarly to left and right.

Moreover, in the following, when identical or similar reference symbols are appended to identical parts and/or parts having similar functions, repeated description thereof may be omitted. Furthermore, dimension ratios in the drawings may differ from actual ratios. In addition, some configurations of the example embodiment may be omitted from the drawings.

A magneto resistive sensor and a manufacturing method for the magneto resistive sensor according to an example embodiment of the present disclosure will be described below.

First, the magneto resistive sensor according to the example embodiment will be described.

A magneto resistive sensor 100 according to this example embodiment may be a rotating magnetic field sensor configured to detect a magnetic field (a rotating magnetic field) that rotates as a symmetrical magnetic field. The rotating magnetic field may be generated, for example, from a rotating magnet, not shown in the drawings.

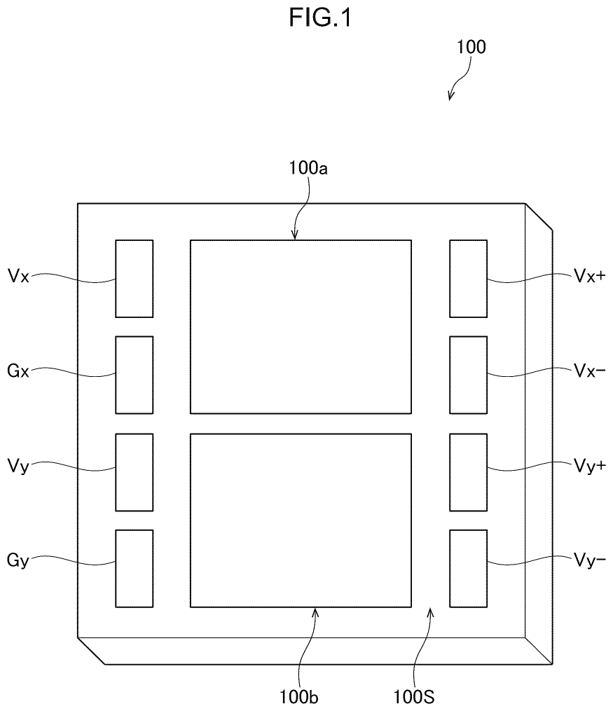

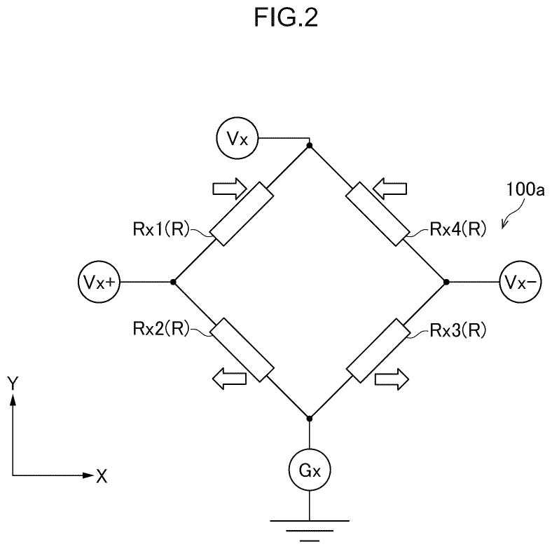

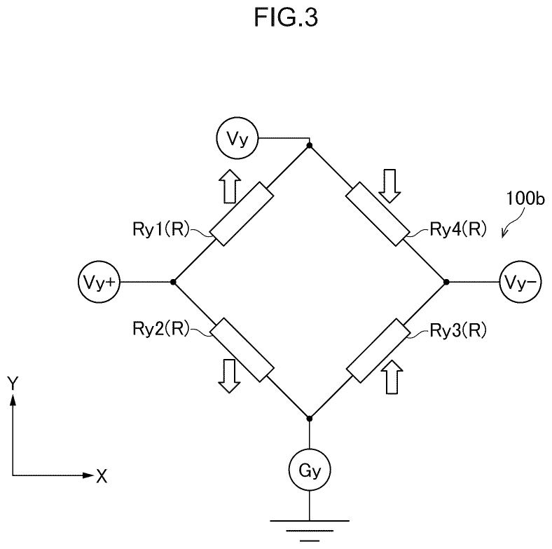

A configuration of the magneto resistive sensor 100 will be described below. FIG. 1 is a view showing a schematic configuration of the magneto resistive sensor 100 according to the example embodiment. FIG. 2 is a circuit diagram showing an example of a circuit configuration of a first magneto resistive sensor unit 100a according to the example embodiment. FIG. 3 is a circuit diagram showing an example of a circuit configuration of a second magneto resistive sensor unit 100b according to the example embodiment. In the examples shown in FIGS. 1 to 3, the magneto resistive sensor 100 may include the first magneto resistive sensor unit 100a and the second magneto resistive sensor unit 100b.

A terminal group may be provided on an upper surface 100s of the magneto resistive sensor 100. Further, as shown in FIGS. 1 and 2, the terminal group of the magneto resistive sensor 100 may include a power supply terminal Vx, output terminals Vx+ and Vx−, and a ground terminal Gx corresponding to the first magneto resistive sensor unit 100a, and a power supply terminal Vy, output terminals Vy+ and Vy−, and a ground terminal Gy corresponding to the second magneto resistive sensor unit 100b.

In the example shown in FIG. 2, the first magneto resistive sensor unit 100a includes four resistance units Rx1, Rx2, Rx3, Rx4 forming a full-bridge Wheatstone bridge circuit. The resistance unit Rx1 may be provided between the power supply terminal Vx and the output terminal Vx+. The resistance unit Rx2 may be provided between the output terminal Vx+ and the ground terminal Gx. The resistance unit Rx3 may be provided between the ground terminal Gx and the output terminal Vx−. The resistance unit Rx4 may be provided between the output terminal Vx− and the power supply terminal Vx. Voltage or current of a predetermined magnitude may be applied to the power supply terminal Vx, and the ground terminal Gx may be connected to the ground.

Similarly, in the example shown in FIG. 3, the second magneto resistive sensor unit 100b may include four resistance units Ry1, Ry2, Ry3, and Ry4 forming a full-bridge Wheatstone bridge circuit. The resistance unit Ry1 may be provided between the power supply terminal Vy and the output terminal Vy+. The resistance unit Ry2 may be provided between the output terminal Vy+ and the ground terminal Gy. The resistance unit Ry3 may be provided between the ground terminal Gy and the output terminal Vy−. The resistance unit Ry4 may be provided between the output terminal Vy− and the power supply terminal Vy. Voltage or current of a predetermined magnitude may be applied to the power supply terminal Vy, and the ground terminal Gy may be connected to the ground.

Note that hereinafter, any one of the resistance units Rx1, Rx2, Rx3, Rx4, Ry1, Ry2, Ry3, and Ry4 may be referred to as a resistance unit R. The resistance unit R may include at least one magnetoresistance element (also referred to hereinafter as an “MR element”).

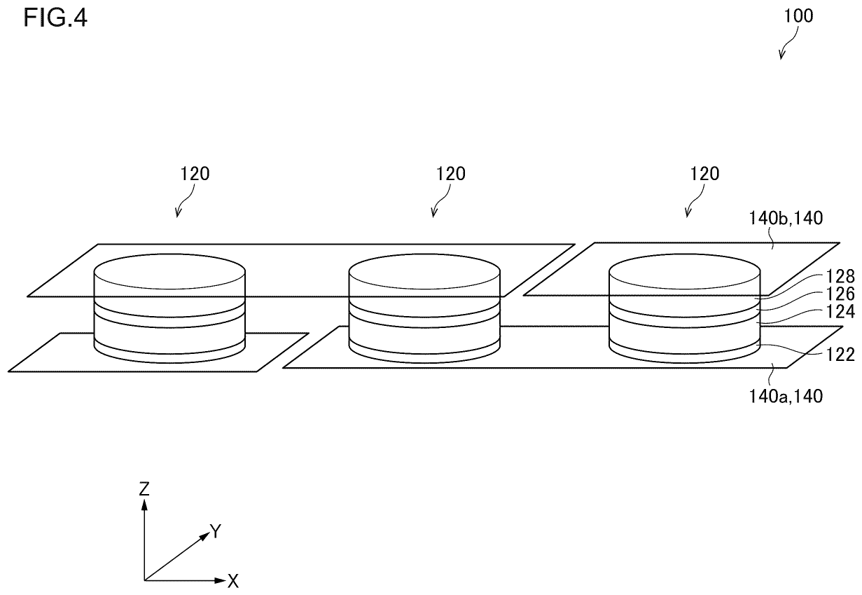

The resistance unit R may include a plurality of MR elements connected in series, for example, and each of a plurality of MR elements 120 may be a spin valve MR element, for example. In this example embodiment, as shown in FIG. 4, the MR elements 120 may be substantially columnar, for example. In this example embodiment, the MR elements 120 may be connected to each other within the magneto resistive sensor 100 via a plurality of connecting layers 140.

As shown in FIG. 4, for example, a first connecting layer 140a of the plurality of connecting layers 140 may contact lower surfaces of two MR elements 120 that are adjacent to each other on the circuit configuration, and these MR elements 120 may be electrically connected to each other. Further, a second connecting layer 140b may contact upper surfaces of two MR elements 120 disposed respectively on two adjacent first connecting layers 140a, and these MR elements 120 may be electrically connected to each other.

Furthermore, as shown in FIG. 4, the MR element 120 may include an antiferromagnetic layer 122, a magnetization fixed layer 124 (a pin layer, a pinned magnetic layer), a gap layer 126, and a free layer 128. As shown in FIG. 4, the antiferromagnetic layer 122 is electrically connected to the first connecting layer 140a, and the free layer 128 is electrically connected to the second connecting layer 140b. The antiferromagnetic layer 122 may include an antiferromagnetic material. The antiferromagnetic layer 122 may generate an exchange coupling with the magnetization fixed layer 124 such that the magnetization direction of the magnetization fixed layer 124 is fixed.

The spin valve MR element 120 may be, for example, a TMR (Tunnel magnetoresistance effect) element or a GMR (Giant magnetoresistance effect) element. When the MR element 120 is a TMR element, the gap layer 126 may be a tunnel barrier layer, for example. When the MR element 120 is a GMR element, the gap layer 126 may be a non-magnetic conductive layer, for example. Note that the arrangement of the antiferromagnetic layer 122, the magnetization fixed layer 124, the gap layer 126, and the free layer 128 of the MR element 120 is not limited to the example shown in FIG. 4. For example, the antiferromagnetic layer 122, the magnetization fixed layer 124, the gap layer 126, and the free layer 128 may be laminated in the Z direction in reverse order to the example shown in FIG. 4.

In the spin valve MR element 120, a resistance value may change in accordance with an angle formed by the direction of magnetization of the free layer 128 relative to the direction of magnetization of the magnetization fixed layer 124 such that when this angle is 0°, the resistance value takes a minimum value, and when this angle is 180°, the resistance value takes a maximum value.

In FIG. 2, the magnetization directions of the magnetization fixed layers 124 in the MR elements 120 of the first magneto resistive sensor unit 100a are indicated by arrows. In the example shown in FIG. 2, the magnetization directions of the magnetization fixed layers 124 of the MR elements 120 in the resistance units Rx1 and Rx3 may be the +X direction, and the magnetization directions of the magnetization fixed layers 124 of the MR elements in the resistance units Rx2 and Rx4 may be the −X direction.

In FIG. 3, the magnetization directions of the magnetization fixed layers 124 in the MR elements 120 of the second magneto resistive sensor unit 100b are indicated by arrows. In the example shown in FIG. 3, the magnetization directions of the magnetization fixed layers 124 of the MR elements 120 in the resistance units Ry1 and Ry3 may be the +Y direction, and the magnetization directions of the magnetization fixed layers 124 of the MR elements 120 in the resistance units Ry2 and Ry4 may be the −Y direction.

A first detection signal Sx output by the first magneto resistive sensor unit 100a may be generated on the basis of a potential difference between the output terminal Vx+ and the output terminal Vx−. The first magneto resistive sensor unit 100a may further include a difference detector that outputs, as the first detection signal Sx, a signal corresponding to the potential difference between the output terminal Vx+ and the output terminal Vx−. In the first detection signal Sx, amplitude or offset adjustments may be carried out on the potential difference between the output terminal Vx+ and the output terminal Vx−.

Similarly, a detection signal Sy output by the second magneto detection unit 100b may be generated on the basis of a potential difference between the output terminal Vy+ and the output terminal Vy−. The second magneto resistive sensor unit 100b may further include a difference detector that outputs, as the second detection signal Sy, a signal corresponding to the potential difference between the output terminal Vy+ and the output terminal Vy−. Likewise with regard to the second detection signal Sy, amplitude or offset adjustments may be carried out on the potential difference between the output terminal Vy+ and the output terminal Vy−.

For example, a waveform of the first detection signal Sx serving as the output of the first magneto resistive sensor unit 100a may form a cos curve that changes in accordance with the rotation angle of the rotating magnetic field, and a waveform of the second detection signal Sy serving as the output of the second magneto resistive sensor unit 100b may form a sin curve that changes in accordance with the rotation angle of the rotating magnetic field.

In the example embodiment, the MR element 120 may have magnetic anisotropy such that the easy axis of magnetization of the free layer 128 is orthogonal to the magnetization direction of the magnetization fixed layer 124. The magnetic anisotropy may also be shape anisotropy. In this case, when seen from above, the MR element 120 may have a substantially oval shape or a substantially rectangular shape in a longitudinal direction orthogonal to the magnetization direction of the magnetization fixed layer 124. Alternatively, a bias magnetic field generation unit may be provided in order to apply to the free layer 128 a bias magnetic field in a direction orthogonal to the magnetization direction of the magnetization fixed layer 124. When the MR element 120 has the magnetic anisotropy described above or is provided with a bias magnetic field generation unit, the magnetization direction of the free layer 128 of the magnetoresistance element 120 in an initial state, which is a state where the magnetic field serving as the detection target is not applied to the magneto resistive sensor 100, may be orthogonal to the magnetization direction of the magnetization fixed layer 124.

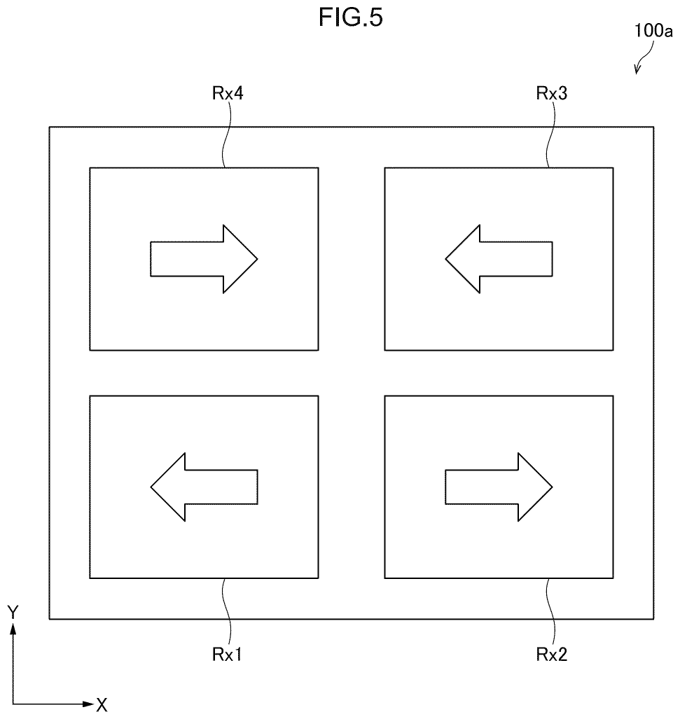

FIG. 5 is a schematic plan view showing the four resistance units Rx1 to Rx4 of the first magneto resistive sensor unit 100a. As shown in FIG. 5, the resistance unit Rx2 may be disposed on the +X direction side of the resistance unit Rx1. The resistance unit Rx3 may be disposed on the +Y direction side of the resistance unit Rx2. The resistance unit Rx4 may be disposed on the −X direction side of the resistance unit Rx3 and the +Y direction side of the resistance unit Rx1. In the first magneto resistive sensor unit 100a, two resistance units R in which the magnetization directions of the magnetization fixed layers 124 of the MR elements 120 are opposite to each other are provided adjacent to each other.

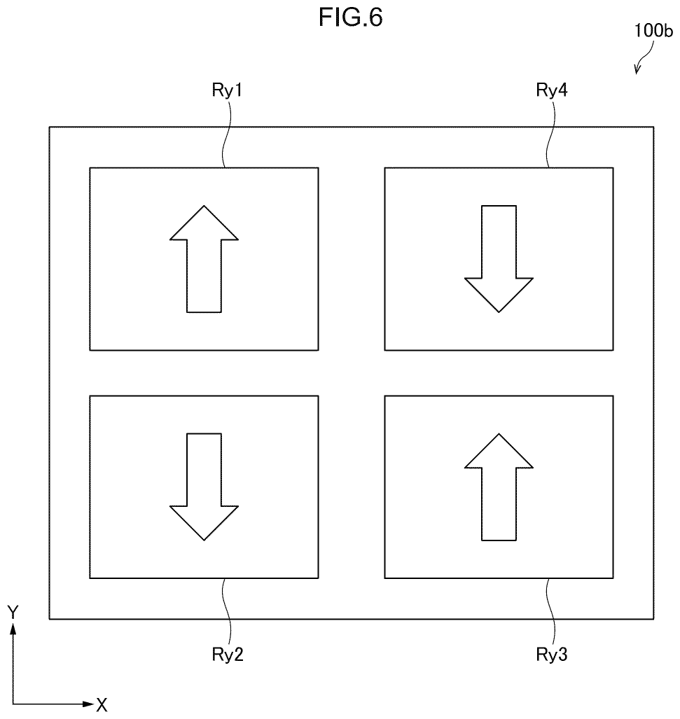

FIG. 6 is a schematic plan view showing the four resistance units Ry1 to Ry4 of the second magneto resistive sensor unit 100b. As shown in FIG. 6, the resistance unit Ry2 may be disposed on the −Y direction side of the resistance unit Ry1. The resistance unit Ry3 may be disposed on the +X direction side of the resistance unit Ry2. The resistance unit Ry4 may be disposed on the +Y direction side of the resistance unit Ry3 and the +X direction side of the resistance unit Ry1. In the second magneto resistive sensor unit 100b, two resistance units R in which the magnetization directions of the magnetization fixed layers 124 of the MR elements 120 are opposite to each other are provided adjacent to each other.

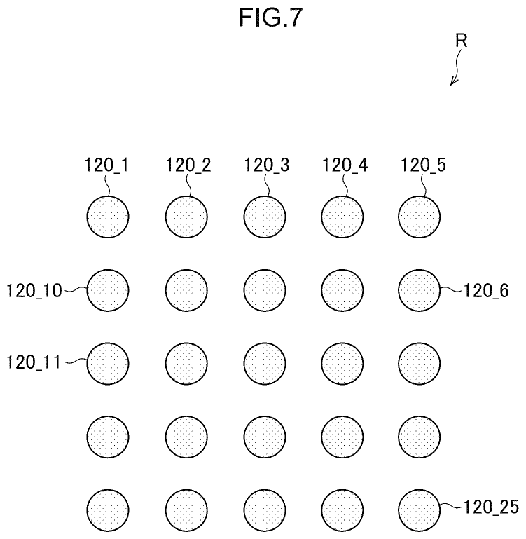

FIG. 7 shows a schematic plan view of the resistance unit R. As shown in FIG. 7, the resistance unit R may include 25 MR elements 120_1, 120_2, . . . , and 120_25 arranged in the X direction and the Y direction in a 5×5 matrix. The 25 MR elements 120_1, 120_2, . . . , and 120_25 may be electrically connected to each other in parallel.

Note that the MR element 120 is not limited to a circular shape (a circular shape when seen from above), as shown in FIG. 7, and may have a polygonal shape such as a square shape. Alternatively, the MR element 120 may have a shape that is long in one direction, such as an elliptical, oval, or rectangular shape.

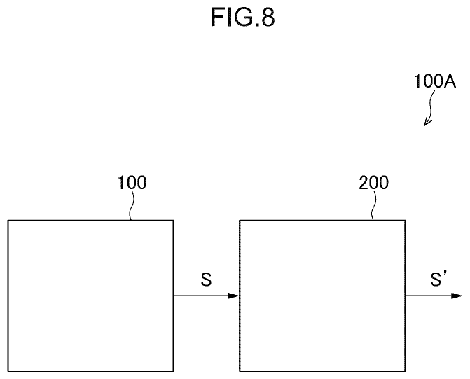

FIG. 8 is a block diagram showing a schematic configuration of a sensor unit 100A according to the example embodiment. As shown in FIG. 8, the sensor unit 100A according to the example embodiment may include the magneto resistive sensor 100 and a signal processing circuit 200. The magneto resistive sensor 100 may output the first and second detection signals Sx and Sy as magnetic signals S by detecting the target magnetic field. The signal processing circuit 200 may process the magnetic signals S input from the magneto resistive sensor 100. The signal processing circuit 200 may execute signal processing on the magnetic signals S and output signals S′.

When the magneto resistive sensor 100 is configured to detect a rotating magnetic field, the signal S′ may be a signal having a correspondence relationship to the rotation angle of the rotating magnetic field or a rotation angle of a magnet, for example. The rotation angle may be determined within a range of no less than 0° and less than 360° by calculating the arc tangent of a ratio of the second detection signal Sy to the first detection signal Sx, for example, or in other words a tan (Sy/Sx).

A manufacturing method for the magneto resistive sensor 100 according to this example embodiment of the present disclosure will be described below.

The manufacturing method for the magneto resistive sensor 100 according to this example embodiment of the present disclosure is a method for manufacturing a magneto resistive sensor including a plurality of magnetoresistance elements, each of which includes a magnetization fixed layer having a laminated structure of an antiferromagnetic film (in the example embodiment, also referred to as an “antiferromagnetic layer”) and a ferromagnetic film (in the example embodiment, also referred to as a “ferromagnetic layer”), the manufacturing method including a first magnetization process for magnetizing a first area of the antiferromagnetic layer by applying a magnetic field in a first magnetization direction and irradiating the first area with a laser beam, and a second magnetization process for magnetizing a second area of the antiferromagnetic layer, the second area not overlapping the first area, after the first magnetization step by applying a magnetic field in a second magnetization direction that differs from the first magnetization direction and irradiating the second area with the laser beam. Furthermore, the second area is adjacent to the first area with a buffer area therebetween. In the second magnetization process, irradiation with a laser beam LB is performed so that the maximum temperature of the first area (the magnetized first area) remains below a blocking temperature Tb.

In the manufacturing method for the magneto resistive sensor 100 according to the example embodiment of the present disclosure, in the process (the first magnetization process) for magnetizing the first area, a magnetic field is applied in the first magnetization direction and the first area is irradiated with the laser beam, while in the process (the second magnetization process) for magnetizing the second area, which is adjacent to the first area with the buffer area therebetween and does not overlap the first area, a magnetic field is applied in the second magnetization direction and the second area is irradiated with the laser beam. Furthermore, in the second magnetization process, irradiation with the laser beam is performed so that the maximum temperature of the first area remains below the blocking temperature. Thus, in the second magnetization process, the magnetization direction of the first area, in which the magnetization direction has been fixed at the first magnetization direction, can be prevented from facing the second magnetization direction. As a result, the first area and the second area can be magnetized respectively to a first magnetization direction Dm1 and a second magnetization direction Dm2, which differ from each other.

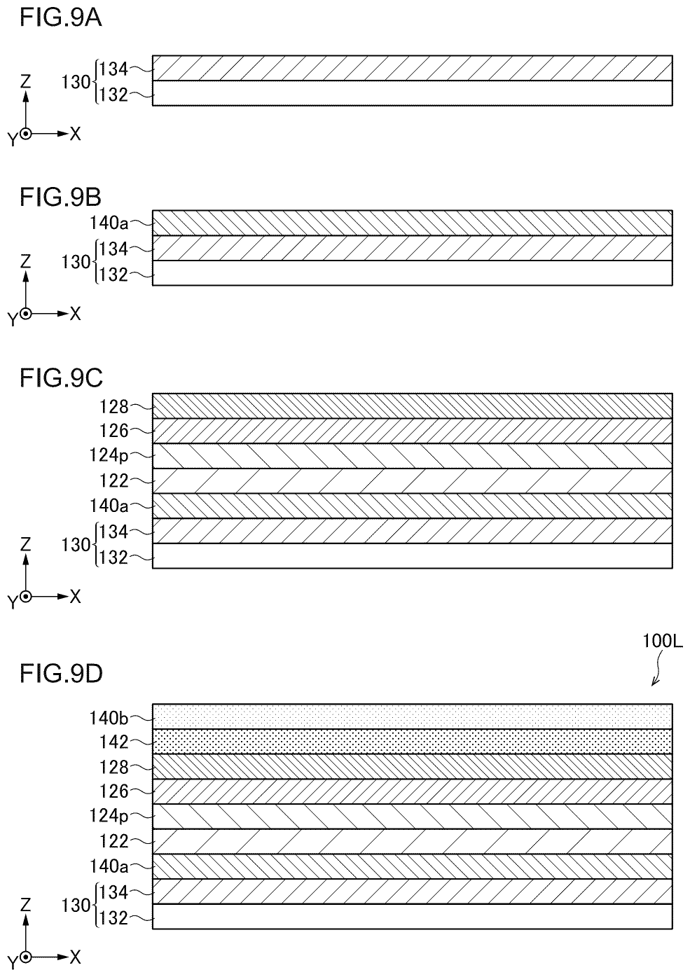

As shown in FIG. 9A, first, for example, a substrate 130 including a semiconductor substrate 132 and an insulating layer 134 may be prepared. The insulating layer 134 may be formed at a thickness of several μm on an upper surface of the semiconductor substrate 132 by CVD (Chemical Vapor Deposition) film formation, for example.

Next, as shown in FIG. 9B, a metal layer serving as the first connecting layer 140a, which forms a lower electrode, may be formed by a method such as sputtering. At this time, a wiring pattern may be formed on the first connecting layer 140a by patterning the metal layer using etching or the like, for example.

Next, as shown in FIG. 9C, the respective layers forming the magnetoresistance element 120 may be formed in succession on the first connecting layer 140a by sputtering or the like. For example, the antiferromagnetic layer 122, a metal layer 124p serving as the magnetization fixed layer 124 (a pin layer, a pinned layer, a pinned magnetic layer), the gap layer 126, and the free layer 128 may be formed in that order. At this time, the respective laminated layers may be patterned into the shape of the magnetoresistance element 120 by etching or the like, for example. When the shape of the magnetoresistance element 120 is formed by patterning, an insulating layer, for example, may be formed to cover the side face of the magnetoresistance element 120. Alternatively, instead of forming the magnetoresistance element 120 by patterning or the like, the magnetoresistance element 120 may be formed by executing magnetization processes to be described below.

Next, as shown in FIG. 9D, a cap layer 142, for example, and the second connecting layer 140b, which forms an upper electrode, may be provided on the magnetoresistance element 120. The cap layer 142 may be formed by a sputtering method or the like so as to have a single-layer structure formed using one of, for example, tantalum, ruthenium, and zirconium, or a two-layer or three-layer structure formed using a plurality thereof.

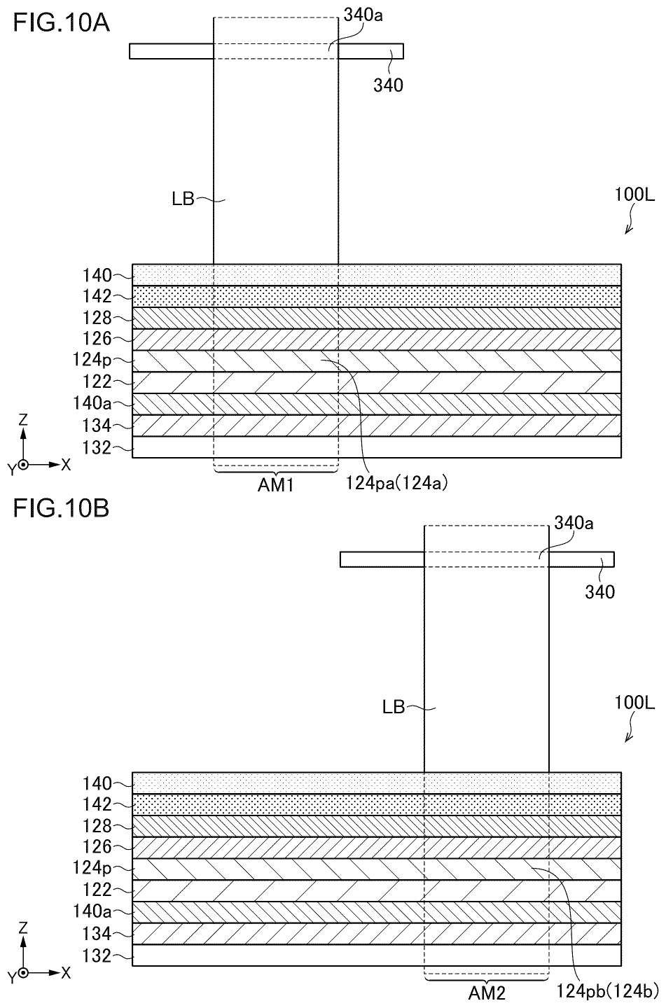

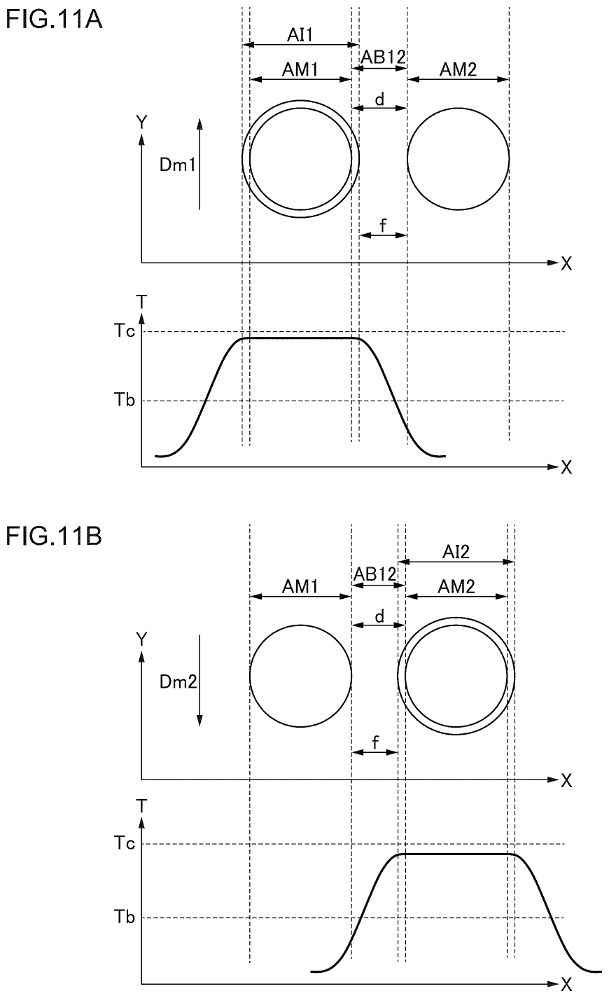

Magnetization processes are performed by laser annealing on a laminated body 100L formed as described above. Processes for forming the magnetization fixed layer 124 by magnetizing the metal layer 124p will be described below with reference to FIGS. 10A and 10B and FIGS. 11A and 11B.

In this example, two magnetized areas having different magnetization directions are formed by performing two magnetization processes on the laminated body 100L. An area in which the magnetization fixed layer is formed in a first magnetization process may serve as a first area AM1, and an area in which the magnetization fixed layer is formed in a second magnetization process may serve as a second area AM2. As shown in FIGS. 11A and 11B, the first area AM1 and the second area AM2 may be arranged so as not to overlap, and may be adjacent to each other in the X direction via a buffer area AB12.

As shown in FIG. 10A, first, in the first magnetization process, a magnetization fixed layer 124a of the first area AM1 is formed by magnetizing a metal layer 124pa, which is the part of the metal layer 124p of the laminated body 100L in the first area AM1. In this process, for example, a magnetic field is applied in the +Y direction so that the magnetization direction Dm1 of the magnetization fixed layer 124a becomes the +Y direction.

FIG. 11A schematically illustrates an X-direction temperature profile of the first area AM1 and the second area AM2 during the first magnetization process. In the first magnetization process, as shown in FIG. 11A, irradiation with the laser beam LB is performed such that an irradiated area AI1 including the first area AM1 serves as the irradiated area. Accordingly, the first irradiated area AI1 is larger than the first area AM1.

At this time, the metal layer 124p provided above the antiferromagnetic layer 122 may be increased in temperature by irradiating the first area AM1 of the antiferromagnetic layer 122 provided below the metal layer 124p with the laser beam so as to heat the antiferromagnetic layer 122. As shown in the lower section of FIG. 11A, the irradiated area AI1 may be irradiated with the laser beam LB so that the first area AM1 becomes equal to or higher than the blocking temperature Tb and lower than a Curie temperature Tc. Further, for example, the temperature of the second area AM2 may be lower than the blocking temperature Tb. Hence, in the buffer area AB12, the temperature may decrease from the first area AM1 toward the second area AM2 from a temperature that is equal to or higher than the blocking temperature Tb and lower than the Curie temperature Tc to a temperature that is lower than the blocking temperature Tb.

Here, the blocking temperature Tb is, for example, a temperature at which an exchange coupling magnetic field disappears, and by setting a ferromagnetic layer at or above the blocking temperature Tb, magnetization of the ferromagnetic layer can be fixed in a predetermined direction. The Curie temperature Tc is, for example, a temperature at or above which ferromagnetic properties are lost, and when the temperature of the magnetization fixed layer reaches or exceeds the Curie temperature Tc, the fixed magnetization can be eliminated.

After completing magnetization of the first area AM1, the second area AM2, which is adjacent to the first area AM1 in the X direction across the buffer area AB12, is magnetized. As shown in FIG. 10B, by magnetizing the second area AM2 of the laminated body 100L, a magnetization fixed layer 124b is formed.

As shown in FIG. 10B, the magnetization fixed layer 124b of the second area AM2 is formed by magnetizing a metal layer 124pb, which is the part of the metal layer 124p of the laminated body 100L in the second area AM2. FIG. 11B schematically illustrates an X-direction temperature profile of the first area AM1 and the second area AM2 during the second magnetization process. For example, in the second magnetization process, as shown in FIG. 11B, irradiation with the laser beam LB is performed so as to form an irradiated area AI2 that includes the second area AM2. Accordingly, the second irradiated area AI2 is larger than the second area AM2.

As is evident from the X-direction temperature profile illustrated schematically in FIG. 11B, in this process, for example, irradiation with the laser beam LB is performed while applying a magnetic field in the −Y direction so that the metal layer 124pb of the second area AM2 becomes equal to or higher than the blocking temperature Tb and lower than the Curie temperature Tc. As a result, the magnetization direction Dm2 of the magnetization fixed layer 124b of the second area AM2 becomes the −Y direction. In other words, the magnetization direction Dm2 of the magnetization fixed layer 124b of the second area AM2 is the opposite direction to the magnetization direction Dm1 of the magnetization fixed layer 124a of the first area AM1.

Furthermore, in the buffer area AB12, the temperature decreases from the second area AM2 toward the first area AM1. For example, the temperature of the first area AM1 is lower than the blocking temperature Tb.

Here, in the second magnetization process, irradiation with the laser beam LB is performed onto the second irradiated area AI2, but the temperature of the first area AM1, which is adjacent to the second area AM2 across the buffer area AB12, may also increase. As a result, the fixed magnetization direction Dm1 of the magnetized first area AM1 may change. Therefore, in the example embodiment, irradiation with the laser beam LB is performed so that the maximum temperature of the already magnetized first area AM1 remains below the blocking temperature Tb. In so doing, it is possible to prevent the magnetization direction Dm1 of the first area AM1 from deviating from the +Y direction so as to face the second magnetization direction Dm2.

Thus, magnetization of the magnetization fixed layer 124a and the magnetization fixed layer 124b of the first area AM1 and the second area AM2 of the magneto resistive sensor 100 is completed.

As devices that use magneto resistive sensors decrease in size and improve in functionality, it may be necessary to further shorten the distance (a distance d (see FIGS. 11A and 11B)) between the magnetoresistance elements 120. By employing the manufacturing method for the magneto resistive sensor 100 according to this example embodiment, the effects of magnetization on an adjacent area that has already been magnetized can be reduced, and as a result, the distance d can be shortened.

In FIG. 11A, a case in which the second area AM2 remains below the blocking temperature Tb during the first magnetization process was described as an example, but in the first magnetization process, the second area AM2 that has not yet been magnetized may be allowed to increase to or above the blocking temperature Tb. For example, when the second area AM2 increases to or above the blocking temperature Tb in the first magnetization process, it is possible that the second area AM2 will be magnetized by the magnetic field applied in the first magnetization direction Dm1 during the first magnetization process. In the subsequent second magnetization process, however, the second area AM2 is further magnetized by the magnetic field in the second magnetization direction Dm2. Therefore, even if the second area AM2 increases to or above the blocking temperature Tb in the first magnetization process, the magnetization direction can be set in the second magnetization direction Dm2 by the second magnetization process.

In FIG. 11B, the distance in the X direction between the first area AM1 and the second area AM2 is indicated by the distance d. As shown in the lower section of FIG. 11B, in the buffer area AB12, the temperature decreases along the X direction from the second area AM2 toward the first area AM1 from a temperature that is equal to or higher than the blocking temperature Tb and lower than the Curie temperature Tc to a temperature that is lower than the blocking temperature Tb. Hence, by setting, as the distance d in the X direction between the first area AM1 and the second area AM2, a distance at which a relationship between the temperature of the first area AM1 and the temperature of the second area AM2 decreases along the X direction from a temperature that is equal to or higher than the blocking temperature Tb and lower than the Curie temperature Tc to a temperature that is lower than the blocking temperature Tb, it is possible to ensure that the magnetization direction of the magnetized first area AM1 does not change during the second magnetization process.

For example, irradiation conditions of the laser beam LB with which irradiation is performed in the second magnetization process may be adjusted so that the temperature of the first area AM1 and the temperature of the second area AM2 during the second magnetization process have the above relationship. Furthermore, in this example embodiment, the Curie temperature Tc of the ferromagnetic metal layer 124p from which the magnetization fixed layer 124 of the magnetoresistance element 120 is formed may be 430° C. or more, for example. Further, the blocking temperature Tb of the ferromagnetic metal layer 124p from which the magnetization fixed layer 124 is formed may be 270° C. or less, for example. Note that in this specification, as the temperatures of the first area AM1 and the second area AM2, the maximum temperatures during the magnetization processes (the first magnetization process and the second magnetization process) may each be equal to or higher than the blocking temperature Tb and lower than the Curie temperature Tc or lower than the blocking temperature Tb. For example, in the second magnetization process, with regard to the first area AM1, the maximum temperature during the second magnetization process may be lower than the blocking temperature Tb, and with regard to the second irradiated area AI2, the maximum temperature during the second magnetization process may be equal to or higher than the blocking temperature Tb and lower than the Curie temperature Tc. For example, in the second magnetization process, irradiation with the laser beam LB may be performed such that the maximum temperature of the first area AM1 is lower than 270° C., i.e., lower than the blocking temperature Tb.

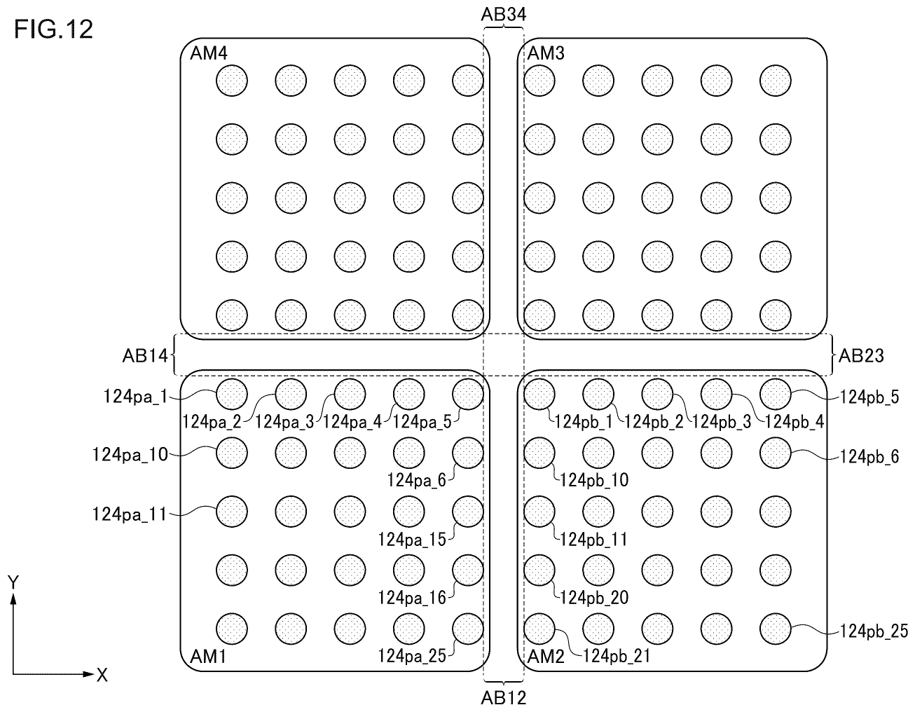

Referring to FIG. 12, an example applied to a case in which three or more magnetoresistance elements 120 are formed will be described. In a state where, during the first magnetization process, a magnetic field is applied in the first magnetization direction Dm1 (for example, the +Y direction) to all of 25 ferromagnetic layers 124p_a1, 124p_a2, . . . , 124p_a25 provided in the first area AM1, irradiation with the laser beam LB may be performed simultaneously. Thus, 25 magnetoresistance elements 120_a1, 120_a2, . . . , 120_a25 all having magnetization fixed layers with magnetization directions fixed in the +Y direction may be formed in the first area AM1.

Next, in a state where, during the second magnetization process, a magnetic field is applied in the second magnetization direction Dm2 (for example, the −Y direction) to all of 25 ferromagnetic layers 124p_b1, 124p_b2, . . . , 124p_b25 provided in the second area AM2, irradiation with the laser beam LB may be performed simultaneously. Thus, 25 magnetoresistance elements 120_b1, 120_b2, . . . , 120_b25 all having magnetization fixed layers with magnetization directions fixed in the −Y direction may be formed in the second area AM2.

In the second magnetization process, the temperatures of the ferromagnetic layers 124pa_5, 124pa_6, 124pa_15, 124pa_16, and 124pa_25 near a boundary with the second area AM2 (the buffer region AB12), among the ferromagnetic layers 124pa_1, . . . , 124pa_25 in the first area AM1, are particularly likely to increase due to the effect of the second area AM2, the temperature of which has increased. According to this example embodiment, however, in the buffer area AB12, the temperature decreases from the second area AM2 toward the first area AM1 so that the temperature of the first area AM1 is lower than the blocking temperature Tb. Accordingly, increases in the temperatures of the ferromagnetic layers 124pa_5, 124pa_6, 124pa_15, 124pa_16, and 124pa_25 near the boundary (when magnetization has already been performed, for example, the magnetization fixed layers 124a_5, 124a_6, 124a_15, 124a_16, and 124a_25) can be suppressed, and the first magnetization direction Dm1 fixed in the first magnetization process can be maintained. For example, in the first magnetization process, when the first magnetization direction is set as the +Y direction and the ferromagnetic layers 124pa_5, 124pa_6, 124pa_15, 124pa_16, and 124pa_25 are magnetized so as to form the magnetization fixed layers 124a_5, 124a_6, 124a_15, 124a_16, and 124a_25, it is possible to prevent the magnetization direction Dm1 of the magnetization fixed layers 124a_5, 124a_6, 124a_15, 124a_16, and 124a_25 from deviating from the +Y direction so as to face the second magnetization direction Dm2.

When a plurality of areas are magnetized simultaneously by the first magnetization process, the antiferromagnetic layer 122, the ferromagnetic layer 124, the gap layer 126, the free layer 128, and so on (FIG. 9C) forming the magnetoresistance element 120 may be laminated in advance, whereupon patterning may be performed so as to form the shape of the area in which the magnetoresistance element 120 is formed.

For example, by reducing the distance (the distance d shown in FIG. 12) between the first area AM1 and the second area AM2, the size of the device can be reduced. However, when the distance between the first area AM1 and the second area AM2 is too small, the first area AM1 may be heated excessively in the second magnetization process such that the temperature of the first area AM1 increases to or above the blocking temperature Tb. At this time, the magnetization direction of the first area AM1, which was fixed at the first magnetization direction Dm1 in the first magnetization process, may change to the second magnetization direction Dm2. In the manufacturing method for the magneto resistive sensor 100 according to the example embodiment of the present disclosure, the second area AM2 is irradiated with the laser beam LB in the second magnetization process so that the first area AM1 remains below the blocking temperature Tb, and therefore a change in the magnetization direction (the first magnetization direction Dm1) of the first area AM1 to the second magnetization direction Dm2 during the second magnetization process can be suppressed.

FIG. 12 additionally shows a third area AM3 and a fourth area AM4. Hence, in this example, four areas provided with 25 magnetoresistance elements 120 may be formed. For example, the magnetization direction of the first area AM1 and the third area AM3 may be the +Y direction, and the magnetization direction of the second area AM2 and the fourth area AM4 may be the +Y direction. For example, the 25 ferromagnetic layers 124p of the first area AM1 may be magnetized in a state where a magnetic field is applied in the +Y direction, and while maintaining the applied magnetic field in the +Y direction, the 25 ferromagnetic layers 124p in the third area AM3 may be magnetized. The ferromagnetic layers 124p of the second area AM2 and the fourth area AM4 may then be magnetized in succession in a state where a magnetic field is applied in the −Y direction.

Similarly in this case, during the magnetization process of the second area AM2, for example, the temperature of the third area AM3, as well as the first area AM1, can be kept below the blocking temperature Tb. Moreover, the temperatures of the first area AM1 and the third area AM3 can likewise be held below the blocking temperature Tb during the magnetization process of the fourth area AM4. Hence, even when the temperatures of the ferromagnetic layers 124p of the second area AM2 increase, the magnetization direction of the magnetization fixed layers 124 of the third area AM3, which have already been magnetized to the +Y direction, does not change, and moreover, even when the temperatures of the ferromagnetic layers 124p of the fourth area AM4 increase, a change in the magnetization direction of the magnetization fixed layers 124 of the magnetized first area AM1 and third area AM3 can be suppressed.

Note that the manufacturing method of this example embodiment can be applied to both a case in which several of the metal layers 124p of the plurality of magnetoresistance elements 120 are magnetized at once and a case in which the metal layers 124p of the plurality of magnetoresistance elements 120 are magnetized one at a time.

FIGS. 11A and 11B show a distance f between the irradiated area (the first irradiated area AI1 and the second irradiated area AI2) and the magnetized area (the first area AM1 and the second area AM2). In the first magnetization process (FIG. 11A), the distance f is the distance in the X direction between the first irradiated area AI1 and the second area AM2, and may be a distance from a +X-direction end of the first irradiated area AI1 to a −X-direction end of the second area AM2. In the second magnetization process (FIG. 11B), the distance f is the distance in the X direction between the second irradiated area AI2 and the first area AM1, and may be a distance from a −X-direction end of the second irradiated area AI2 to a +X-direction end of the first area AM1.

In the first magnetization process and/or the second magnetization process of the example embodiment, irradiation with the laser beam LB may be performed so that the distance f between the irradiated area (the first irradiated area AI1 and the second irradiated area AI2) and the adjacent element area (the first area AM1 and the second area AM2) is at least ½ the distance d between the areas forming the magnetoresistance element 120. In other words, in the example embodiment, irradiation with the laser beam LB may be performed in the second magnetization process so that the shortest distance f from the boundary of the irradiated area AI2 irradiated with the laser beam LB to the boundary of the first area AM1 is at least ½ the shortest distance d from the boundary of the second area AM2 to the boundary of the first area AM1. Furthermore, likewise in the first magnetization process, irradiation with the laser beam LB may be performed so that the shortest distance f from the boundary of the irradiated area AI1 irradiated with the laser beam to the boundary of the second area AM2 is at least ½ the shortest distance d from the boundary of the first area AM1 to the boundary of the second area AM2. Thus, for example, the second irradiated area AI2, which is the area irradiated with the laser beam in the second magnetization process, can be formed at a size that allows the second area AM2 serving as the magnetization target to be irradiated sufficiently with the laser beam. Moreover, for example, the irradiated area AI1 that is irradiated with the laser beam LB in the first magnetization process and the irradiated area AI2 that is irradiated with the laser beam LB in the second magnetization process do not overlap, and as a result, irradiation with the laser beam LB can be executed efficiently.

In this example embodiment, irradiation with the laser beam LB may be performed in the second magnetization process so that the aforesaid distance f is less than ¾ of d, for example. Similarly, irradiation with the laser beam LB may be performed in the first magnetization process so that the distance f is less than ¾ of d, for example.

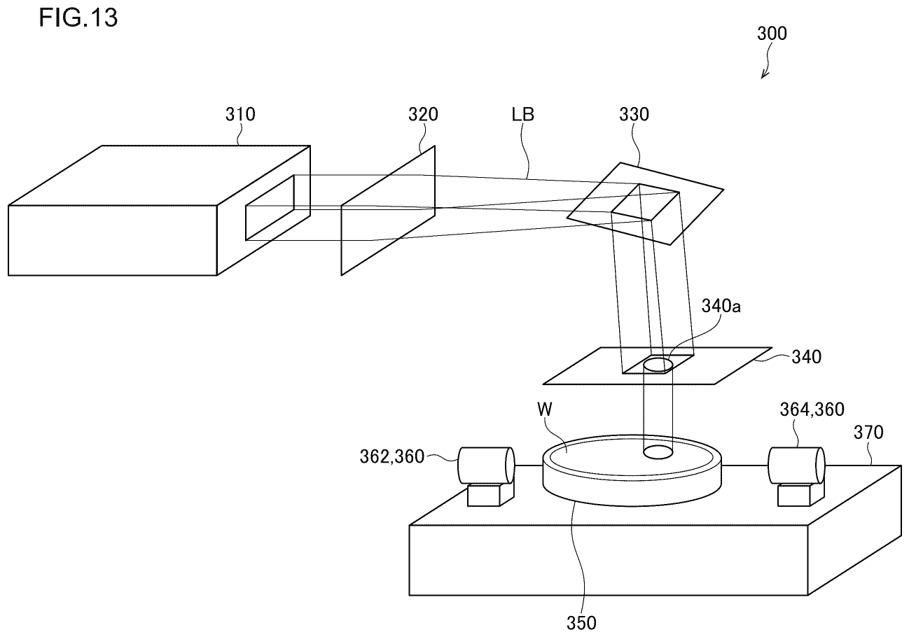

In the example embodiment, as described above, the Curie temperature Tc and the blocking temperature Tb of the ferromagnetic layer 124p forming the magnetization fixed layer 124 of the magnetoresistance element 120 are set respectively at 430° C. or more and 270° C. or less, for example. At this time, in order to set the second irradiated area AI2 so that f is d/2 or more and d or less, irradiation with the laser beam LB may be performed so that, for example, in the part of the buffer area AB12 between the second irradiated area AI2 and the first area AM1, a temperature gradient along the X direction from the second irradiated area AI2 toward the first area AM1, or an average of the temperature gradient in this part of the buffer area AB12, is (Tc−Tb)/(d/2) or more. Thus, the temperature in the second irradiated area AI2 can be set at or above the blocking temperature Tb and below the Curie temperature Tc, and the temperature in the first area AM1 can be kept below the blocking temperature Tb, and as a result, the second area AM2 can be magnetized to the second magnetization direction Dm2 without changing the already fixed magnetization direction Dm1 of the first area AM1. Furthermore, when, for example, the antiferromagnetic layer 122 above which the magnetoresistance element 120 is formed has a property whereby the temperature thereof decreases at a rate of (Tc−Tb)/(d/2) or more with increasing distance from the boundary of the area that is irradiated with the laser beam, the temperature in the second irradiated area AI2 can be set at or above the Curie temperature Tc, and the temperature in the first area AM1 can be kept below the blocking temperature Tb. Note that the antiferromagnetic layer 122 can also be formed so that the temperature thereof decreases at the rate described above by, for example, adjusting the material used to form the antiferromagnetic layer 122 or conditions such as the temperature, humidity, and air pressure of the environment in which the magnetization processes are executed. Moreover, the rate at which the temperature of the antiferromagnetic layer 122 decreases can also be adjusted by adjusting the irradiation conditions of the laser beam LB, such as an opening (an opening portion 340 to be described below (FIG. 13), for example) that defines the irradiated areas AI irradiated with the laser beam LB.

For example, in a case where the magnetoresistance element 120 is formed so that the distance d (the distance between the first area AM1 and the second area AM2) is 50 μm or more, when the Curie temperature Tc and the blocking temperature Tb are 430° C. and 270° C., respectively, irradiation with the laser beam LB may be performed such that the temperature gradient along the X direction from the second irradiated area AI2 toward the magnetized first area AM1 during the second magnetization process is equal to or less than (430° C.−270° C.)/25 μm=6.4° C./μm. For example, the antiferromagnetic layer 122 has a property whereby, in an environment regulated to 13° C. or higher and lower than 33° C., the temperature thereof decreases at a rate of 6.4° C./μm or less with increasing distance from the boundary of the irradiated area AI2 irradiated with the laser beam, and therefore, by performing irradiation with the laser beam LB in this environment so that in the second magnetization process, the shortest distance f from the boundary of the irradiated area AI2 irradiated with the laser beam to the boundary of the magnetized first area AM1 is 25 μm or more, the magnetized first area AM1 and the magnetized second area AM2, the distance d between which is 50 μm or more, can be formed so that the magnetization directions thereof are respectively the first magnetization direction Dm1 and the second magnetization direction Dm2.

Note that in order to reduce the size of the device in which the magneto resistive sensor is used even in a case where the distance d is 50 μm or more, as described above, for example, when the magnetoresistance element 120 is to be formed so that the distance d is 200 μm or less, irradiation with the laser beam LB may be performed such that the temperature gradient along the X direction from the second irradiated area AI2 toward the magnetized first area AM1 during the second magnetization process equals or exceeds (430° C.−270° C.)/100 μm=1.6° C./μm. For example, the antiferromagnetic layer 122 has a property whereby, in an environment regulated to 13° C. or higher and lower than 33° C., the temperature thereof decreases at a rate of 1.6° C./μm or more and 6.4° C./μm or less with increasing distance from the boundary of the irradiated area AI2 irradiated with the laser beam, and therefore, by performing irradiation with the laser beam LB in this environment so that in the second magnetization process, the shortest distance f from the boundary of the irradiated area AI2 irradiated with the laser beam to the boundary of the magnetized first area AM1 is 25 μm or more and 100 μm or less, the magnetized first area AM1 and the magnetized second area AM2, the distance d between which is 50 μm or more and 200 μm or less, can be formed so that the magnetization directions thereof are respectively the first magnetization direction Dm1 and the second magnetization direction Dm2.

A manufacturing method for the magneto resistive sensor 100 according to this example embodiment and manufacturing conditions thereof for further reducing d is described below.

When, for example, the antiferromagnetic layer 122 has a property whereby, in an environment regulated to 18° C. or higher and lower than 28° C., the temperature thereof decreases at a rate of more than 6.4° C./μm and 10.7° C./μm or less with increasing distance from the boundary of the irradiated area (the second irradiated area AI2) irradiated with the laser beam LB, irradiation with the laser beam may be performed in this environment such that in the second magnetization process, the distance f is 15 μm or more and less than 25 μm. When the temperature decreases at a rate of more than 6.4° C./μm and 10.7° C./μm or less, the first area AM1 and the second area AM2 can be separated by 30 μm or more and less than 50 μm while setting the second irradiated area AI2 at or above the blocking temperature Tb and below the Curie temperature Tc and keeping the magnetized first area AM1 below the blocking temperature Tb in the second magnetization process.

Furthermore, when, for example, the antiferromagnetic layer 122 has a property whereby, in an environment regulated to 21° C. or higher and lower than 25° C., the temperature thereof decreases at a rate of more than 10.7° C./μm and 32.0° C./μm or less with increasing distance from the boundary of the irradiated area (the second irradiated area AI2) irradiated with the laser beam, irradiation with the laser beam LB may be performed in this environment such that in the second magnetization process, the distance f is 5 μm or more and less than 15 μm. When the temperature decreases at a rate of more than 10.7° C./μm and 32.0° C./μm or less, the first area AM1 and the second area AM2 can be separated by 10 μm or more and less than 30 μm while setting the second irradiated area AI2 at or above the blocking temperature Tb and below the Curie temperature Tc and keeping the magnetized first area AM1 below the blocking temperature Tb in the second magnetization process.

Moreover, when, for example, the antiferromagnetic layer 122 has a property whereby, in an environment regulated to 22° C. or higher and lower than 24° C., the temperature thereof decreases at a rate of more than 32.0° C./μm and 106.7° C./μm or less with increasing distance from the boundary of the irradiated area (the second irradiated area AI2) irradiated with the laser beam LB, irradiation with the laser beam may be performed in this environment such that in the second magnetization process, the distance f is 1.5 μm or more and less than 5 μm. When the temperature decreases at a rate of more than 32.0° C./μm and 106.7° C./μm or less, the first area AM1 and the second area AM2 can be separated by 3 μm or more and less than 10 μm while setting the second irradiated area AI2 at or above the blocking temperature Tb and below the Curie temperature Tc and keeping the magnetized first area AM1 below the blocking temperature Tb in the second magnetization process.

Moreover, when, for example, the antiferromagnetic layer 122 has a property whereby, in an environment regulated to 22° C. or higher and lower than 24° C. and to a humidity of 10% or more and less than 70%, the temperature thereof decreases at a rate of more than 106.7° C./μm and 320.0° C./μm or less with increasing distance from the boundary of the irradiated area (the second irradiated area AI2) irradiated with the laser beam LB, irradiation with the laser beam LB may be performed in this environment such that in the second magnetization process, the distance f is 0.5 μm or more and less than 1.5 μm. When the temperature decreases at a rate of more than 106.7° C./μm and 320.0° C./μm or less, the first area AM1 and the second area AM2 can be separated by 1 μm or more and less than 3 μm while setting the second irradiated area AI2 at or above the blocking temperature Tb and below the Curie temperature Tc and keeping the magnetized first area AM1 below the blocking temperature Tb in the second magnetization process.

In addition, when, for example, the antiferromagnetic layer 122 has a property whereby, in an environment regulated to 22.5° C. or higher and 23.5° C. or lower, to a humidity of 20% or more and less than 60%, and to an air pressure of 913 hPa or more and less than 1113 hPa, the temperature thereof decreases at a rate of more than 320.0° C./μm and 640.0° C./μm or less with increasing distance from the boundary of the irradiated area (the second irradiated area AI2) irradiated with the laser beam LB, irradiation with the laser beam LB may be performed in this environment after adjusting a distance between an aperture opening of the laser beam LB (the opening portion 340 to be described below (FIG. 13), for example) and the antiferromagnetic layer 122 to less than 0.1 μm such that in the second magnetization process, the distance f is 0.25 μm or more and less than 0.5 μm. When the temperature decreases at a rate of more than 320.0° C./μm and 640.0° C./μm or less, the first area AM1 and the second area AM2 can be separated by 0.5 μm or more and less than 1 μm while setting the second irradiated area AI2 at or above the blocking temperature Tb and below the Curie temperature Tc and keeping the magnetized first area AM1 below the blocking temperature Tb in the second magnetization process.

In the manufacturing method for the magneto resistive sensor 100 according to the example embodiment of the present disclosure, other processes may be executed in addition to the processes described above. For example, laser annealing may be executed before executing the first magnetization process. Laser annealing may also be executed after executing the second magnetization process. Furthermore, laser annealing may be executed before executing the first magnetization process and after executing the second magnetization process.

A laser annealing device 300 used in the manufacturing method for the magneto resistive sensor 100 according to the example embodiment will be described below with reference to FIG. 13. The laser annealing device 300 according to the example embodiment of the present disclosure may be used in the first magnetization process and the second magnetization process of the manufacturing method for the magneto resistive sensor 100, for example.

The laser annealing device 300 may include, for example, a laser light source 310 that emits the laser beam LB toward the magnetization target area (the first area AM1 and the second area AM2) of a substrate W mounted on a stage 350, and the opening portion 340, which is disposed between the laser light source 310 and the stage 350 and provided so that when the laser beam LB passes through, the irradiated area (the first irradiated area AI1 and the second irradiated area AI2) on the substrate W is larger than the magnetization target area (the first area AM1 and the second area AM2). The laser annealing device 300 may further include, for example, a reflector 330, an electromagnet 360, a movable platform 370, and so on, and moreover, one or a plurality of shutters, mirrors, and so on may be provided on a light path of the laser beam LB, and a control unit or the like for controlling the laser annealing device 300 may also be provided.

The electromagnet 360 may be configured to include a first electromagnet 362 and a second electromagnet 364 arranged so as to face each other via the substrate W, and to generate a magnetic field that is applied to the substrate W. The movable platform 370 may be configured to be capable of rotating the stage 350 on which the substrate W is mounted, for example. For example, when the second magnetization direction Dm2 is to be applied to the substrate W after shifting to the second magnetization process from the first magnetization direction Dm1 applied to the substrate W in the first magnetization process, the magnetization direction may be changed by rotating the substrate W mounted on the stage 350 using the movable platform 370. For example, the movable platform 370 may be configured so as to set the first magnetization direction Dm1 and the second magnetization direction Dm2 so as to differ from each other by 90° or 180° by rotating the substrate W 90° or 180°.

In the laser annealing device 300, the respective sizes of the irradiated areas (the first irradiated area AI1 and the second irradiated area AI2) described above and the distance f between the irradiated area and the magnetization target area (the first area AM1 and the second area AM2) may be adjusted by adjusting the size of an opening 340a of the opening portion 340, for example. As an example, when a stencil mask having the opening 340a is used as the opening portion 340, a plurality of stencil masks with openings 340a of different sizes and/or shapes may be prepared, and by selecting an appropriate stencil mask in accordance with the irradiation conditions of the laser beam LB and so on, the sizes of the irradiated areas (the first irradiated area AI1 and the second irradiated area AI2) and the distance f may be adjusted. Furthermore, the irradiation conditions of the laser beam LB can be adjusted by adjusting the height at which the stencil mask is disposed.

The example embodiment described above is for facilitating understanding of the disclosure and is not to be construed as limiting the technology. The respective elements of the example embodiment as well as the arrangements, materials, conditions, shapes, sizes, and so on thereof are not limited to those illustrated in the example embodiment and may be modified as appropriate. Furthermore, configurations disclosed in different example embodiments may be partially replaced or combined.

For example, the manufacturing method for the magneto resistive sensor 100 according to this example embodiment can be applied to manufacture of the magnetic sensor unit 100A, and the magnetic sensor unit 100A may be used in an application for detecting positional change in the XY plane and positional change in the Z direction from change in a Z-direction magnetic field. Examples of applications employing this sensor may include a strain gauge, an angle sensor, a position sensor, a compass, a current sensor, and a switch, as well as electronic devices such as an actuator used in a joint mechanism or the like of a robot, an opening/closing detection mechanism for a laptop computer, a joystick, a brushless motor, and a magnetic encoder.

What is claimed is:

1. A manufacturing method for a magneto resistive sensor comprising a plurality of magnetoresistance elements, each of which includes a magnetization fixed layer having a laminated structure of an antiferromagnetic film and a ferromagnetic film, the manufacturing method comprising:
a first magnetization step for magnetizing a first area of the antiferromagnetic layer by applying a magnetic field in a first magnetization direction and irradiating the first area with a laser beam; and
a second magnetization step for magnetizing a second area of the antiferromagnetic layer, the second area not overlapping the first area, after the first magnetization step by applying a magnetic field in a second magnetization direction that differs from the first magnetization direction and irradiating the second area with the laser beam,
wherein the second area is adjacent to the first area with a buffer area therebetween, and
in the second magnetization step, irradiation with the laser beam is performed so that a maximum temperature of the first area remains below a blocking temperature.

2. The manufacturing method according to claim 1, wherein the antiferromagnetic layer has a property whereby, in an environment regulated to 13° C. or higher and lower than 33° C., the temperature thereof decreases at a rate of 6.4° C./μm or less with increasing distance from a boundary of the irradiated area irradiated with the laser beam, and
in the second magnetization step, irradiation with the laser beam is performed in the environment so that a shortest distance from the boundary of the irradiated area irradiated with the laser beam to a boundary of the magnetized first area is 25 μm or more.

3. The manufacturing method according to claim 1, wherein the antiferromagnetic layer has a property whereby, in an environment regulated to 18° C. or higher and lower than 28° C., the temperature thereof decreases at a rate of more than 6.4° C./μm and 10.7° C./μm or less with increasing distance from a boundary of the irradiated area irradiated with the laser beam, and
in the second magnetization step, irradiation with the laser beam is performed in the environment so that a shortest distance from the boundary of the irradiated area irradiated with the laser beam to a boundary of the magnetized first area is 15 μm or more and less than 25 μm.

4. The manufacturing method according to claim 1, wherein the antiferromagnetic layer has a property whereby, in an environment regulated to 21° C. or higher and lower than 25° C., the temperature thereof decreases at a rate of more than 10.7° C./μm and 32.0° C./μm or less with increasing distance from a boundary of the irradiated area irradiated with the laser beam, and
in the second magnetization step, irradiation with the laser beam is performed in the environment so that a shortest distance from the boundary of the irradiated area irradiated with the laser beam to a boundary of the magnetized first area is 5 μm or more and less than 15 μm.

5. The manufacturing method according to claim 1, wherein the antiferromagnetic layer has a property whereby, in an environment regulated to 22° C. or higher and lower than 24° C., the temperature thereof decreases at a rate of more than 32.0° C./μm and 106.7° C./μm or less with increasing distance from a boundary of the irradiated area irradiated with the laser beam, and
In the second magnetization step, irradiation with the laser beam is performed in the environment so that a shortest distance from the boundary of the irradiated area irradiated with the laser beam to a boundary of the magnetized first area is 1.5 μm or more and less than 5 μm.

6. The manufacturing method according to claim 1, wherein the antiferromagnetic layer has a property whereby, in an environment regulated to 22° C. or higher and lower than 24° C. and to a humidity of 10% or more and less than 70%, the temperature thereof decreases at a rate of more than 106.7° C./μm and 320.0° C./μm or less with increasing distance from a boundary of the irradiated area irradiated with the laser beam, and
in the second magnetization step, irradiation with the laser beam is performed in the environment so that a shortest distance from the boundary of the irradiated area irradiated with the laser beam to a boundary of the magnetized first area is 0.5 μm or more and less than 1.5 μm.

7. The manufacturing method according to claim 1, wherein the antiferromagnetic layer has a property whereby, in an environment regulated to 22.5° C. or higher and 23.5° C. or lower, to a humidity of 20% or more and less than 60%, and to an air pressure of 913 hPa or more and less than 1113 hPa, the temperature thereof decreases at a rate of more than 320.0° C./μm and 640.0° C./μm or less with increasing distance from a boundary of the irradiated area irradiated with the laser beam, and
in the second magnetization step, irradiation with the laser beam is performed in the environment after adjusting a distance between the aperture opening and the antiferromagnetic layer to less than 0.1 μm so that a shortest distance from the boundary of the irradiated area irradiated with the laser beam to a boundary of the magnetized first area is 0.25 μm or more and less than 0.5 μm.

8. The manufacturing method according to claim 2, wherein, in the second magnetization step, irradiation with the laser beam is performed so that the maximum temperature of the first area is lower than 270° C., which is lower than the blocking temperature.
